(19) United States
(12) Patent Application Publication
(10) Pub. No.: US 2025/0208193 A1
(43) Pub. Date: Jun. 26, 2025

(54) CONNECTING CONDITION DIAGNOSIS APPARATUS AND SYSTEM THEREOF

(71) Applicant: HYUNDAI MOBIS CO., LTD., Seoul (KR)

(72) Inventor: Gyu Hyeon SEO, Suwon-si (KR)

(73) Assignee: HYUNDAI MOBIS CO., LTD., Seoul (KR)

(21) Appl. No.: 18/811,047

(22) Filed: Aug. 21, 2024

(30) Foreign Application Priority Data
Dec. 21, 2023 (KR) 10-2023-0188506

(51) Int. Cl. G01R 31/28; G01R 31/52

(52) U.S. Cl. CPC G01R 31/2812; G01R 31/2808; G01R 31/52

(57) ABSTRACT

A connecting condition diagnosis apparatus connected to an electronic device including first and second ports electrically short-circuited with each other, and a system therefor are provided. The apparatus includes: first and second connection terminals respectively connected to the first and second ports of the electronic device by wires; and a diagnosis circuit connected to the first and second connection terminals and configured to diagnose whether the connecting condition diagnosis apparatus is connected to the electronic device. The diagnosis circuit includes a first impedance between the first connection terminal and the second connection terminal, and the first impedance includes a passive element.

### CROSS-REFERENCE TO RELATED APPLICATION(S)

This application claims priority under 35 U.S.C. § 119 of Korean Patent Application No. 10-2023-0188506, filed on Dec. 21, 2023, in the Korean Intellectual Property Office, the disclosure of which is incorporated herein by reference in its entirety for all purposes.

### BACKGROUND

### 1. Field

The following disclosure relates to connecting condition diagnosis apparatus and system, and more particularly, to a connecting condition diagnosis apparatus and a system enabling a connecting condition with an electronic device to be distinguished in greater detail.

### 2. Description of the Related Art

A vehicle system installed with various devices may include a circuit for checking whether the device is connected to the vehicle system through a connector or a cable. As an example, the circuit for checking whether the device is connected to the system may include a pull-up circuit including a first resistor having one end connected to a sensing voltage and the other end connected to a second resistor, and a second resistor having one end connected to the other end of the first resistor and the other end connected to ground. In this case, the various devices may include a node connected to a node between the first resistor and the second resistor and outputting a ground voltage when connected to the system.

If the device is not physically connected to the vehicle system, the sensing voltage may be output to the node between the first resistor and the second resistor. On the other hand, if the device is physically connected to the vehicle system through the connector or the cable, the device may output the ground voltage to the circuit for checking whether the device is connected to the system through a terminal, and a potential of the node between the first resistor and the second resistor may be changed to the ground voltage.

The vehicle system may detect the change in the potential of the node between the first resistor and the second resistor, and determine that the device is not connected to the vehicle system when the potential of the node is the same as the sensing voltage, and determine that the device is connected to the vehicle system when the potential of the node is the same as the ground voltage.

However, in the circuit as described above, the node between the first resistor and the second resistor has no choice but to have two values, such as the sensing voltage and the ground voltage. Accordingly, the circuit may only determine whether the device is connected to or disconnected from the system, and is unable to identify their connecting condition in detail. In addition, the same ground voltage as that of the case where the device is connected to the system may be applied even when a short-circuit occurs in the connection, which may cause the connecting condition to be incorrectly recognized.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In a general aspect of the disclosure, a connecting condition diagnosis apparatus connected to an electronic device including first and second ports electrically short-circuited with each other, includes: first and second connection terminals respectively connected to the first and second ports of the electronic device by wires; and a diagnosis circuit connected to the first and second connection terminals and to diagnose whether the connecting condition diagnosis apparatus is connected to the electronic device, wherein the diagnosis circuit includes a first impedance between the first connection terminal and the second connection terminal, and wherein the first impedance includes a passive element.

The diagnosis circuit may further include a second impedance between the first connection terminal and a power source; and the diagnosis circuit may be configured to externally provide an output node comprising a node in contact with the first impedance, the first connection terminal, and the second impedance, and the second impedance may include a passive element.

The diagnosis circuit may further include a third impedance between the second connection terminal and ground, and the third impedance may include a passive element.

Each of the first impedance, the second impedance, and the third impedance may include a resistor.

When a rated voltage of the power source is V_{s_r}, a real part of the first impedance is R₁, a real part of the second impedance is R₂, and a real part of the third impedance is R₃,
the real part of the first impedance, the real part of the second impedance, and the real part of the third impedance may satisfy an expression below:

$$\vert {V}_{s\_r} \cdot ( {R}_{2} + {R}_{3} ) / ( {R}_{1} + {R}_{2} + {R}_{3} ) - {V}_{s\_r} \cdot {R}_{3} / ( {R}_{1} + {R}_{3} ) \vert \geq {V}_{s\_r} / 10.$$

When a rated voltage of the power source is V_{s_r}, a real part of the first impedance is R₁, a real part of the second impedance is R₂, and a real part of the third impedance is R₃,
the real part of the first impedance, the real part of the second impedance, and the real part of the third impedance simultaneously may satisfy Expression 1 and Expression 2 shown below:

$$\vert {V}_{s\_r} \cdot {V}_{s\_r} \cdot ( {R}_{2} + {R}_{3} ) / ( {R}_{1} + {R}_{2} + {R}_{3} ) \vert \geq {V}_{s\_r} / 10 , and \qquad [ Expression 1 ]$$

$$\vert {V}_{s\_r} \cdot ( {R}_{2} + {R}_{3} ) / ( {R}_{1} + {R}_{2} + {R}_{3} ) \vert \geq {V}_{s\_r} / 10. \qquad [ Expression 2 ]$$

When a rated voltage of the power source is V_{s_r}, a real part of the first impedance is R₁ and a real part of the third impedance is R₃,
the real part of the first impedance, the real part of the second impedance, and the real part of the third impedance simultaneously may satisfy Expression 3 and Expression 4 shown below:

$$\vert {V}_{s\_r} - {V}_{s\_r} \cdot {R}_{3} / ( {R}_{1} + {R}_{3} ) \vert \geq {V}_{s\_r} / 10 , and \qquad [ Expression 3 ]$$

$$\vert {V}_{s\_r} \cdot {R}_{3} / ( {R}_{1} + {R}_{3} ) \vert \geq {V}_{s\_r} / 10. \qquad [ Expression 4 ]$$

In another general aspect of the disclosure, a connecting condition diagnosis system, includes: a connecting condition diagnosis apparatus connected to an electronic device including first and second ports electrically short-circuited with each other; and a controller connected to the connecting condition diagnosis apparatus, wherein the connecting condition diagnosis apparatus includes a first connection terminal and a second connection terminal respectively connected to the first and second ports of the electronic device by wires, the connecting condition diagnosis circuit connected to the first and second connection terminals and configured to diagnose whether the connecting condition diagnosis apparatus is connected to the electronic device, wherein the connecting condition diagnosis circuit includes: a first impedance between the first connection terminal and the second connection terminal; and a second impedance disposed between the first connection terminal and a power source; and a third impedance between the second connection terminal and ground, wherein the first impedance, the second impedance, and the third impedance are passive elements, wherein the connecting condition diagnosis circuit is configured to externally provide an output node which is a node in contact with the first impedance, the first connection terminal, and the second impedance, and wherein, based on a potential of an output node of the connecting condition diagnosis apparatus, the controller is configured to diagnose a connecting condition between the electronic device and the connecting condition diagnosis apparatus as one of: a first condition where any one of the first and the second connection terminals of the connecting condition diagnosis apparatus is not connected to the first or second port of the electronic device; a second condition where the electronic device and the connecting condition diagnosis apparatus are connected to each other; or a third condition where an electrical path between the electronic device and the connecting condition diagnosis apparatus is short-circuited with the outside.

The controller may be further configured to determine, as the first condition, the connecting condition between the electronic device and the connecting condition diagnosis apparatus in response to the potential of the output node being more than a predetermined first reference voltage.

The controller may be further configured to, as the second condition, the connecting condition between the electronic device and the connecting condition diagnosis apparatus in response to the potential of the output node being less than the first reference voltage and greater than a predetermined second reference voltage, and the second reference voltage may be less than the first reference voltage.

The controller may be configured to determine, as the third condition, the connecting condition between the electronic device and the connecting condition diagnosis apparatus in response to the potential of the output node being less than the second reference voltage, or greater than a predetermined third reference voltage, and the third reference voltage may be greater than the first reference voltage or the second reference voltage.

When a rated voltage of the power source is V_{s_r}, a real part of the first impedance is R₁, a real part of the second impedance is R₂, and a real part of the third impedance is R₃,
the first reference voltage may be less than a value of V_{s_r}·(R₂+R₃)/(R₁+R₂+R₃), and the first reference voltage is more than or equal to a largest value between V_{s_r}·α·(R₂+R₃)/(R₁+R₂+R₃) and V_{s_r}·β·(R₃)/(R₁+R₃), and
where, α is a constant having a value between 0.8 and 0.9, and β is a constant having a value between 1.1 and 1.2.

When a rated voltage of the power source is V_{s_r}, a real part of the first impedance is R₁, a real part of the second impedance is R₂, and a real part of the third impedance is R₃,
the second reference voltage may be less than a value of V_{s_r}·γ·(R₃)/(R₁+R₃), and
where, γ is a constant having a value between 0.8 and 0.9.

When a rated voltage of the power source is V_{s_r}, a real part of the first impedance is R₁, a real part of the second impedance is R₂, and a real part of the third impedance is R₃,
the third reference voltage is more than a value of V_{s_r}·δ·(R₂+R₃)/(R₁+R₂+R₃), and
where, δ is a constant having a value of 1.1 or more.

In response to the second reference voltage being sufficiently less than the potential of the output node in the second condition, the controller may be further configured not to misdiagnose the potential of the output node in the second condition as the third condition.

In response to the third reference voltage being sufficiently larger than the potential of the output node in the first condition, the controller may be further configured to not misdiagnose the potential of the output node in the first condition as the third condition.

Based on at least one of the first reference voltage, the second reference voltage, the third reference voltage, or any combination thereof, the controller may be further configured to diagnose at least one of a connection between the system and the electronic device, a condition of the electronic device, or a combination thereof.

Other features and aspects will be apparent from the following detailed description, the drawings, and the claims.

### BRIEF DESCRIPTION OF THE DRAWINGS

FIG. 1 shows a schematic diagram of a connecting condition diagnosis apparatus according to the present disclosure.

FIG. 2 shows a schematic diagram of a connecting condition diagnosis system of the present disclosure.

FIG. 3 shows a schematic diagram of the connecting condition diagnosis system of the present disclosure under a first condition.

FIG. 4 shows a schematic diagram of the connecting condition diagnosis system of the present disclosure under a second condition.

FIG. 5 shows a schematic diagram of the connecting condition diagnosis system of the present disclosure under a third condition.

### DETAILED DESCRIPTION

The above-mentioned objects, features, and advantages will become more obvious from the following embodiments provided in relation to the accompanying drawings. The following descriptions of specific structures and functions are provided only to describe the embodiments based on a concept of the present disclosure. Therefore, the embodiments of present disclosure may be implemented in various forms, and the present disclosure is not limited thereto. The embodiments of the present disclosure may be variously modified and may have several forms, and specific embodiments are thus shown in the accompanying drawings and described in detail in the specification or the present application. However, it is to be understood that the present disclosure is not limited to the specific embodiments, and includes all modifications, equivalents, and substitutions, included in the spirit and scope of the present disclosure. Terms such as “first”, “second”, or the like may be used to describe various components, and the components are not to be construed as being limited to the terms. The terms are used only to distinguish one component from another component. For example, a “first” component may be named a “second” component and the “second” component may also be named the “first” component, without departing from the scope of the present disclosure. It is to be understood that when one component is referred to as being “connected to” or “coupled to” another component, the corresponding component may be connected or coupled directly to another component or connected or coupled to another component with a third component interposed therebetween. On the other hand, it is to be understood that when one component is referred to as being “connected directly to” or “coupled directly to” another component, one component may be connected to or coupled to another component without a third component interposed therebetween. Other expressions to describe a relationship between the components, i.e., “˜between” and “directly between” or “adjacent to” and “directly adjacent to”, should be interpreted in the same manner as above. Terms used in the specification are used only to describe the specific embodiments rather than limiting the present disclosure. A term of a singular number used herein is intended to include its plural number unless explicitly indicated otherwise. It is to be understood that terms “include”, “have”, and the like, used in the specification specify the presence of features, numerals, steps, operations, components, parts, or a combination thereof stated in the specification, and do not preclude the presence or addition of one or more other features, numerals, steps, operations, components, parts, or a combination thereof. Unless defined otherwise, it is to be understood that all the terms including technical and scientific terms, used herein, have the same meanings as those that are generally understood by those skilled in the art to which the present disclosure pertains. Terms generally used and defined by a dictionary should be interpreted as having the same meanings as meanings within a context of the related art, and should not be interpreted as having ideal or excessively formal meanings unless being clearly defined in the present application. Hereinafter, an embodiment of the present disclosure is described in detail with reference to the accompanying drawings. Like reference numerals proposed in each drawing denote like components.

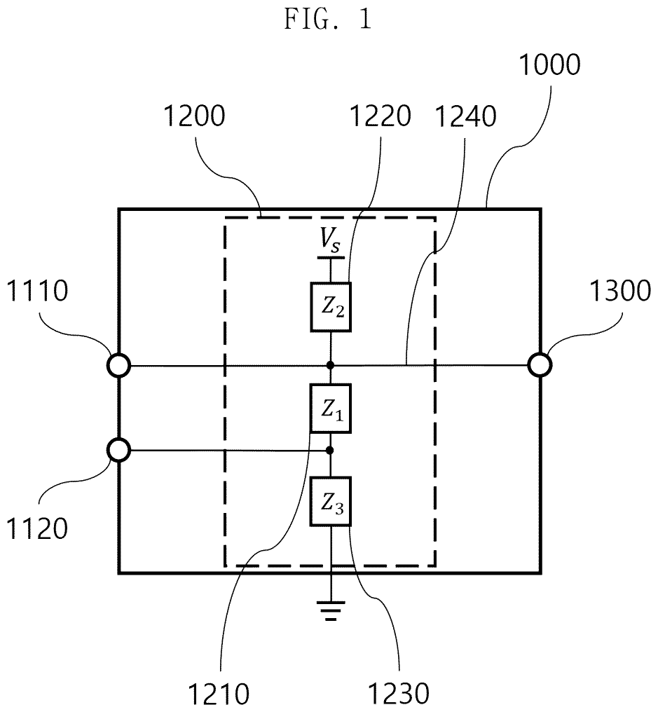

FIG. 1 shows a schematic diagram of a connecting condition diagnosis apparatus according to the present disclosure.

Unlike the prior art, a connecting condition diagnosis apparatus 1000 of the present disclosure may diagnose its connection state with an electronic device 3000 by using two contact points instead of one contact point. Referring to FIG. 1, the connecting condition diagnosis apparatus 1000 of the present disclosure may include a first connection terminal 1110, a second connection terminal 1120, and a diagnosis circuit 1200 that may be connected to the electronic device 3000 including first and second ports 3110 and 3120 electrically short-circuited with each other. The diagnosis circuit 1200 may be a controller or a processor.

The description below describes each component of the connecting condition diagnosis apparatus 1000.

The first and second connection terminals 1110 and 1120 may respectively be connected to the first and second ports 3110 and 3120 of the electronic device 3000. In detail, the first port 3110 of the electronic device 3000 may be electrically connected to the first connection terminal 1110 of the connecting condition diagnosis apparatus 1000 through a first port wire 3210, and the second port 3120 of the electronic device 3000 may be electrically connected to the second connection terminal 1120 of the connecting condition diagnosis apparatus 1000 through a second port wire 3220. In addition, the electronic device 3000 and the connecting condition diagnosis apparatus 1000 may use any means through which the device and apparatus may be electrically connected to each other, such as a cable in addition to the wire. In another embodiment, the electronic device 3000 and the connecting condition diagnosis apparatus 1000 may be connected to each other by using the contact point such as a pogo pin terminal without using a wired manner such as the wire.

The diagnosis circuit 1200 may be connected to the electronic device 3000 through the first and second connection terminals 1110 and 1120, and diagnose whether the connecting condition diagnosis apparatus 1000 and the electronic device 3000 are connected to each other. In detail, the diagnosis circuit 1200, which is connected to the electronic device 3000 through the first and second connection terminals 1110 and 1120, may output different voltage levels for each connecting condition between the electronic device 3000 and the connecting condition diagnosis apparatus 1000.

The description describes a detailed configuration of the diagnosis circuit 1200. The diagnosis circuit 1200 may largely include a first impedance 1210, a second impedance 1220, a third impedance 1230, and an output node 1240. In FIG. 1, Z1 indicates the first impedance 1210, Z2 indicates the second impedance 1220, and Z3 indicates the third impedance 1230.

The diagnosis circuit 1200 may include the first impedance 1210, which is a passive element, between the first connection terminal 1110 and the second connection terminal 1120. In detail, the first impedance 1210 may have one end connected to the first connection terminal 1110 and the other end connected to the second connection terminal 1120.

In addition, the diagnosis circuit 1200 may further include the second impedance 1220 which is a passive element disposed between the first connection terminal 1110 and a power source Vs. In detail, the second impedance 1220 may have one end connected to the power source Vs and the other end connected to the first connection terminal 1110.

Here, the power source Vs is a voltage source required to generate different voltages through the diagnosis circuit 1200 based on the connecting condition. To this end, the connecting condition diagnosis apparatus 1000 may include a separate voltage source, or may receive power from an external source and connected to one end of the second impedance 1220.

The diagnosis circuit 1200 may include the third impedance 1230, which is a passive element, between the second connection terminal 1120 and ground. In detail, the third impedance 1230 may have one end connected to the second connection terminal 1120 and the other end connected to the ground.

Meanwhile, the first to third impedances 1210, 1220, and 1230 may include a passive element. The first to third impedances 1210, 1220, and 1230 may include one or more of a capacitor and an inductor in addition to a resistor. In particular, the first to third impedances 1210, 1220, and 1230 in the present disclosure may include the resistor. Accordingly, each of the first to third impedances 1210, 1220, and 1230 may include a combination of the resistor, the capacitor, and the inductor.

In conclusion, the first to third impedances 1210, 1220, and 1230 may always have a real part by including the resistor. Therefore, a voltage of the power source Vs may be distributed to the output node 1240 of the connecting condition diagnosis apparatus 1000 without being affected by a frequency or the like, and the output node 1240 may thus output a potential at a certain level.

The diagnosis circuit 1200 may externally provide the output node 1240 which is a node in contact with the first impedance 1210, the first connection terminal 1110, and the second impedance 1220. In detail, the first to third impedances 1210, 1220, and 1230 of the diagnosis circuit 1200 may distribute the voltage of the power source Vs. As a result, the voltage may be applied to the output node 1240 which is the node in contact with the first impedance 1210 and the second impedance 1220, and different levels of voltage may thus be externally provided based on the connecting condition of the electronic device 3000 and the connecting condition diagnosis apparatus 1000.

Types of the connecting conditions may include a first condition where any one of the first and second connection terminals 1110 and 1120 of the connecting condition diagnosis apparatus 1000 is not connected to the first or second port 3110 or 3120 of the electronic device, a second condition where the electronic device 3000 and the connecting condition diagnosis apparatus 1000 are connected to each other, or a third condition where an electrical path between the electronic device 3000 and the connecting condition diagnosis apparatus 1000 is short-circuited with the outside. Here, the third condition where the electrical path between the electronic device 3000 and the connecting condition diagnosis apparatus 1000 is short-circuited with the outside may include a ground short-circuit condition where the electrical path is grounded and a ground voltage thus appears, and a power source short-circuit condition where the electrical path is short-circuited with the power source Vs and a power source voltage thus appears.

Meanwhile, a rated voltage of the power source Vs may be defined as V_{s_r}, the real part of the first impedance 1210 may be defined as R₁, the real part of the second impedance 1220 may be defined as R₂, and the real part of the third impedance 1230 may be defined as R₃.

In the first condition, a real part of the potential of the output node 1240 may have the same value as an expression shown below.

$${V}_{s\_r} \cdot ( {R}_{2} + {R}_{3} ) / ( {R}_{1} + {R}_{2} + {R}_{3} )$$

In the second condition, the real part of the potential of the output node 1240 may have the same value as an expression shown below.

$${V}_{s\_r} \cdot ( {R}_{3} ) / ( {R}_{1} + {R}_{3} )$$

In the third condition and the ground short-circuit condition, the potential of the output node 1240 may have the same potential value as a ground potential. In the third condition and the power source short-circuit condition, the potential of the output node 1240 may have the same potential value as the power source Vs.

The description describes below a process of determining the connecting condition based on a voltage level.

To clearly distinguish a voltage range for each connecting condition, the diagnosis circuit 1200 of the connecting condition diagnosis apparatus 1000 according to the present disclosure may set each of the real part of the first impedance 1210, the real part of the second impedance 1220, and the real part of the third impedance 1230 to a value satisfying a certain condition. To this end, the diagnosis circuit 1200 may be designed for the voltages of the output node 1240 in the first to third conditions to be different from one another by 10% or more of the rated voltage of the power source. The reason is that the first to third conditions may be accurately recognized through a difference in the voltages of the output node 1240 only when there is a sufficient difference in the voltages of the output node 1240 for the respective conditions. Here, the sufficient difference may indicate a voltage of 10% or more of the rated voltage of the power source Vs. The first to third conditions may be accurately distinguished from one another without being affected by external noise or the like when the diagnosis circuit is designed for the difference between the voltages of the output node 1240 to be output by 10% or more of the rated voltage of the power source Vs.

The potential of the output node 1240 in the first condition and the potential of the output node 1240 in the second condition may be different from each other by 10% or more of the rated voltage of the power source Vs. In detail, the real part of the first impedance 1210, the real part of the second impedance 1220, and the real part of the third impedance 1230 may satisfy an expression shown below.

$$\vert {V}_{s\_r} \cdot ( {R}_{2} + {R}_{3} ) / ( {R}_{1} + {R}_{2} + {R}_{3} ) - {V}_{s\_r} \cdot {R}_{3} / ( {R}_{1} + {R}_{3} ) \vert \geq {V}_{s\_r} / 10$$

The potential of the output node 1240 in the first condition and the potential of the output node 1240 in the power source short-circuit condition of the third condition may be different from each other by 10% or more of the rated voltage of the power source Vs. In detail, the real part of the first impedance 1210, the real part of the second impedance 1220, and the real part of the third impedance 1230 may satisfy Expression 1 below.

$$\vert {V}_{s\_r} - {V}_{s\_r} \cdot ( {R}_{2} + {R}_{3} ) / ( {R}_{1} + {R}_{2} + {R}_{3} ) \vert \geq {V}_{s\_r} / 10 \qquad [ Equation 1 ]$$

Simultaneously, the potential of the output node 1240 in the first condition and the potential of the output node 1240 in the ground short-circuit condition of the third condition may be different from each other by 10% or more of the rated voltage of the power source Vs. In detail, the real part of the first impedance 1210, the real part of the second impedance 1220, and the real part of the third impedance 1230 may satisfy Expression 2 below.

$$\vert {V}_{s\_r} \cdot ( {R}_{2} + {R}_{3} ) / ( {R}_{1} + {R}_{2} + {R}_{3} ) \vert \geq {V}_{s\_r} / 10 \qquad [ Equation 2 ]$$

The potential of the output node 1240 in the second condition and the potential of the output node 1240 in the power source short-circuit condition of the third condition may be different from each other by 10% or more of the rated voltage of the power source Vs. In detail, the real part of the first impedance 1210 and the real part of the third impedance 1230 may satisfy Expression 3 below.

$$\vert {V}_{s\_r} - {V}_{s\_r} \cdot {R}_{3} / ( {R}_{1} + {R}_{3} ) \vert \geq {V}_{s\_r} / 10 \qquad [ Expression 3 ]$$

Simultaneously, the potential of the output node 1240 in the second condition and the potential of the output node 1240 in the ground short-circuit condition of the third condition may be different from each other by 10% or more of the rated voltage of the power source Vs. In detail, the real part of the first impedance 1210 and the real part of the third impedance 1230 may satisfy Expression 4 below.

$$\vert {V}_{s\_r} \cdot {R}_{3} / ( {R}_{1} + {R}_{3} ) \vert \geq {V}_{s\_r} / 10 \qquad [ Expression 4 ]$$

As a result, the first to third conditions may be accurately distinguished without being affected by the noise by designing the diagnosis circuit 1200 for the respective voltages of the output node 1240 to be more by 10% or more of the rated voltage of the power source Vs in the first to third conditions.

Meanwhile, the connecting condition diagnosis apparatus 1000 may include a separate output terminal 1300 to externally provide the potential of the output node 1240 of the diagnosis circuit 1200. To this end, the connecting condition diagnosis apparatus 1000 may also include a line to externally output the potential of the output node 1240 by connecting the wire or the cable to the output node 1240.

In conclusion, unlike the prior art, the connecting condition diagnosis apparatus 1000 in the present disclosure may output the different voltages from the electronic device 3000 based on the various connecting conditions by using two contact points to thus allow the connecting condition to be checked in more detail, and may output the voltage which is different from the voltage in the connecting condition even in the short-circuit condition to thus allow the connection conditions to be distinguished.

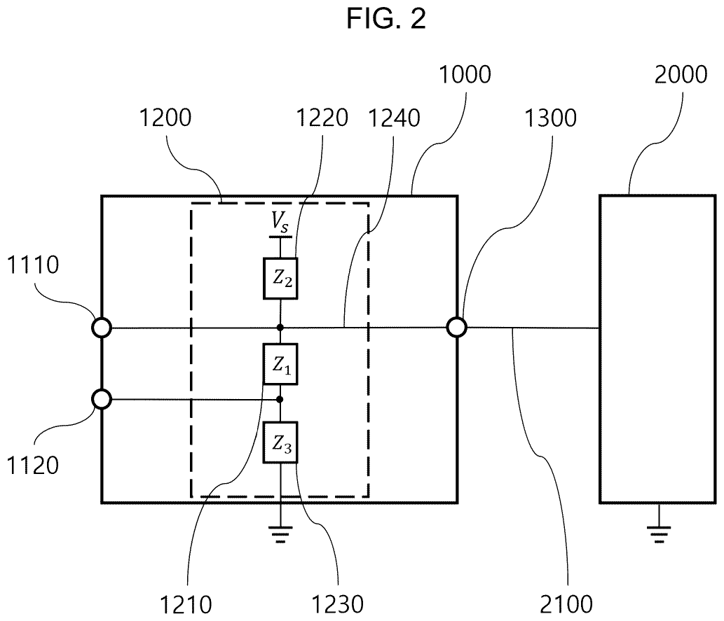

Referring to FIG. 2, a connecting condition diagnosis system may be configured by further including a controller 2000, specifically determining whether the connecting condition diagnosis apparatus 1000 and the electronic device 3000 are connected to each other, in addition to the connecting condition diagnosis apparatus 1000 of the present disclosure.

Based on the potential of the output node 1240 included in the connecting condition diagnosis apparatus 1000, the controller 2000 may determine the connecting condition between the electronic device 3000 and the connecting condition diagnosis apparatus 1000 as one of the first condition where any one of the first and second connection terminals 1110 and 1120 of the connecting condition diagnosis apparatus 1000 is not connected to the first or second port 3110 or 3120 of the electronic device 3000, the second condition where the electronic device 3000 and the connecting condition diagnosis apparatus 1000 are connected to each other, or the third condition where the electrical path between the electronic device 3000 and the connecting condition diagnosis apparatus 1000 is short-circuited with the outside. In detail, the controller 2000 may determine the connecting condition between the electronic device 3000 and the connecting condition diagnosis apparatus 1000 as one of the first to third conditions based on a potential level received from the output node 1240 of the connecting condition diagnosis apparatus 1000. The description describes below details of the first to third conditions which may be determined by the controller 2000.

The controller 2000 may be grounded to detect the potential of the output node 1240 included in the connecting condition diagnosis apparatus 1000. In addition, the controller 2000 may be connected to the output node 1240 of the connecting condition diagnosis apparatus 1000 through the controller cable 2100.

The controller cable 2100 may be the same type of wire or cable as the first or second port wire 3210 or 3220. Meanwhile, the connecting condition diagnosis apparatus 1000 may include the output terminal 1300 connected to the output node 1240. In this case, the controller 2000 may be connected to the output terminal 1300 through the controller cable 2100.

The controller 2000 may be connected to another device in addition to the connecting condition diagnosis apparatus 1000, and the controller 2000 may transmit a control command to another device based on the connecting condition between the electronic device 3000 and the connecting condition diagnosis apparatus 1000. As an example, the controller 2000 may be a battery management unit (BMS). When the controller 2000 is mounted on a vehicle, the battery management system (BMS), which includes a feature of the controller 2000, may check the connection or non-connection of the electronic device in detail when the vehicle is operated. Therefore, the controller 2000 may control another device or system more organically based on the connecting condition of the electronic device 3000.

In conclusion, the controller 2000 may enable the connecting condition between the electronic device 3000 and the connecting condition diagnosis apparatus 1000 to be determined more systematically and specifically based on the potential of the output node 1240 of the connecting condition diagnosis apparatus 1000.

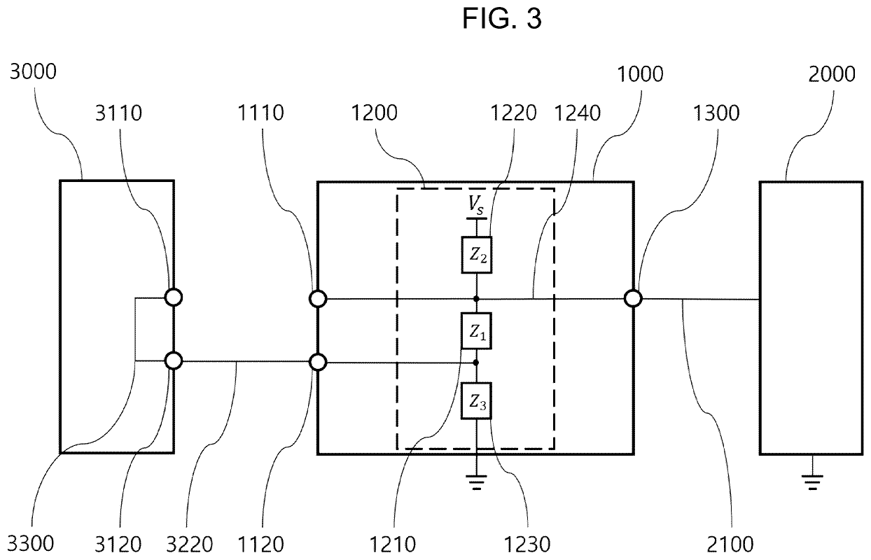

Next, the description describes the connecting condition diagnosis system in the first to third conditions with reference to FIGS. 3 to 5.

FIG. 3 shows a schematic diagram of the connecting condition diagnosis system of the present disclosure under a first condition.

The description describes the electronic device 3000 which is a subject of the connecting condition diagnosis. The electronic device 3000 may include the first port 3110 and the second port 3120 electrically short-circuited with each other. In detail, the electronic device 3000 may include the first port 3110 and the second port 3120 that may be electrically connected to the first and second connection terminals 1110 and 1120 of the connecting condition diagnosis apparatus 1000, respectively. In an embodiment, the first port 3110 or the second port 3120 may include a connector, the pogo pin, or the like.

The electronic device 3000 may include a connection circuit 3300 for electrically short-circuiting the first port 3110 and the second port 3120. Therefore, when the first port 3110 and the second port 3120 are short-circuited by the connection circuit 3300, the potential of the first port 3110 and the potential of the second port 3120 may be the same as each other. In an embodiment, the connecting condition diagnosis apparatus 1000 may include the connection circuit 3300 for the first port 3110 and the second port 3120 to be connected to each other by a conductor or the like.

In another embodiment, the connection circuit 3300 may include a switch disposed between the first port 3110 and the second port 3120 to selectively short-circuit the first port 3110 and the second port 3120. In detail, the switch of the connection circuit 3300 may be controlled to be turned on only when the electronic device 3000 needs to recognize whether or not the electronic device 3000 is connected to another device. In the other cases, the switch of the connection circuit 3300 may be controlled to be turned off to selectively short-circuit the first port 3110 and the second port 3120. Alternatively, in order to control a timing for recognizing the connection, the electronic device 3000 may selectively short-circuit the first port 3110 and the second port 3120 by turning on or off the switch of the connection circuit 3300. Therefore, the potentials of the first connection terminal 1110 and the second connection terminal 1120 may become the same as each other when the electronic device 3000 is normally connected to the connecting condition diagnosis apparatus 1000.

Meanwhile, the electronic device 3000 may be a power conversion device, for example. An example of the power conversion device may include the converter, the inverter, or the like.

The description describes the case where the connecting condition between the electronic device 3000 and the connecting condition diagnosis apparatus 1000 is the first condition with reference to FIG. 3.

Based on the potential of the output node 1240 of the connecting condition diagnosis apparatus 1000, the controller 2000 may determine the connecting condition between the electronic device 3000 and the connecting condition diagnosis apparatus 1000 as the first condition where any one of the first and second connection terminals 1110 and 1120 included in the connecting condition diagnosis apparatus 1000 is not connected to the first or second port 3110 or 3120 of the electronic device 3000. In detail, the condition where any one of the first and second connection terminals 1110 and 1120 is not connected to the first or second port 3110 or 3120 of the electronic device 3000 may include two examples.

The first example may be a non-connecting condition where the electronic device 3000 is not connected to the connecting condition diagnosis apparatus 1000, and the first and second connection terminals 1110 and 1120 are all open by being connected to no terminals of the first and second ports 3110 and 3120 of the electronic device 3000.

The second example may be a short-circuit condition where the electronic device 3000 and the connecting condition diagnosis apparatus 1000 used to be connected to each other, and the disconnection then occurs as the wire is damaged by an external force or the like applied thereto, thus forming no electrical path between the first connection terminal 1110 and the first port 3110 or between the second connection terminal 1120 and the second port 3120.

In conclusion, the first condition is a condition that includes the non-connecting condition and the disconnecting condition.

As an example of the first condition, FIG. 3 shows a situation where the first port 3110 of the electronic device 3000 and the first connection terminal 1110 of the connecting condition diagnosis apparatus 1000 are not connected to each other due to the disconnection of the first port wire 3210. As another example of the disconnection, the second port 3120 of the electronic device 3000 and the second connection terminal 1120 of the connecting condition diagnosis apparatus 1000 may not be connected to each other due to the disconnection of the second port wire 3220. A condition where the disconnections of both the first port wire 3210 and the second port wire 3220 occur may be the same as the condition where the electronic device 3000 is not connected to the connecting condition diagnosis apparatus 1000. The potential of one end of the first impedance 1210 and the potential of the other end of the first impedance 1210 may be different from each other when the device connecting condition between the electronic device 3000 and the connecting condition diagnosis apparatus 1000 has the first condition.

Therefore, when the power source is V, the real part of the first impedance 1210 is R₁, the real part of the second impedance 1220 is R₂, and the real part of the third impedance 1230 is R₃, by the connection relationship of the first to third impedances 1210, 1220, and 1230 included in the diagnosis circuit 1200 of the connecting condition diagnosis apparatus 1000, the real part of the potential of the output node 1240 included in the connecting condition diagnosis apparatus 1000 in the first condition may have the same value as in an expression shown below.

$${V}_{s} \cdot ( {R}_{2} + {R}_{3} ) / ( {R}_{1} + {R}_{2} + {R}_{3} )$$

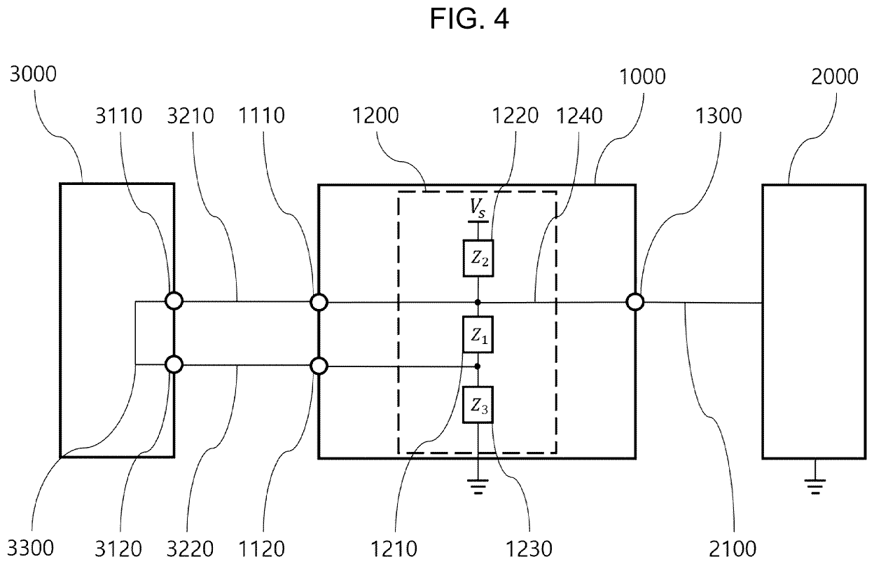

The description describes the case where the connecting condition between the electronic device 3000 and the connecting condition diagnosis apparatus 1000 is the second condition with reference to FIG. 4.

FIG. 4 shows a schematic diagram of the connecting condition diagnosis system of the present disclosure under a second condition.

Based on the potential of the output node 1240 of the connecting condition diagnosis apparatus 1000, the controller 2000 may determine the connecting condition between the electronic device 3000 and the connecting condition diagnosis apparatus 1000 as the second condition where the electronic device 3000 and the connecting condition diagnosis apparatus 1000 are connected to each other. In detail, the second condition may be a case where the first and second ports 3110 and 3120 of the electronic device 3000 and the first and second connection terminals 1110 and 1120 of the connecting condition diagnosis apparatus 1000 are respectively connected by the wires, and the electronic device 3000 and the connecting condition diagnosis apparatus 1000 are thus electrically connected to each other.

In the case where the connecting condition between the electronic device 3000 and the connecting condition diagnosis apparatus 1000 is the second condition, the first and second ports 3110 and 3120 may be short-circuited. Therefore, the first impedance 1210 may also be short-circuited, and the potential of one end of the first impedance 1210 and the potential of the other end of the first impedance 1210 may become the same as each other.

Therefore, a current may not flow to the first impedance 1210 because the first impedance 1210 is short-circuited. Here, by the connection relationship of the second impedance 1220 and the third impedance 1230 included in the diagnosis circuit 1200 of the connecting condition diagnosis apparatus 1000, the real part of the potential of the output node 1240 of the connecting condition diagnosis apparatus 1000 in the second condition may have the same value as in an expression shown below.

$${V}_{s} \cdot ( {R}_{3} ) / ( {R}_{1} + {R}_{3} )$$

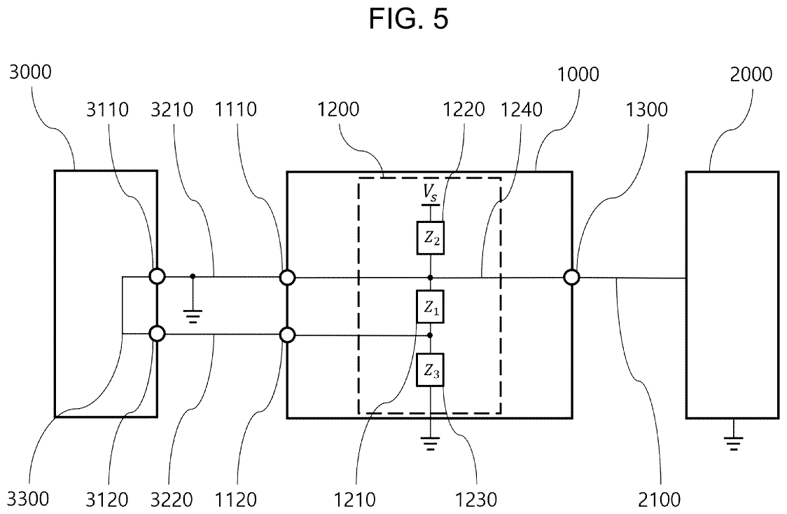

The description describes the case where the connecting condition between the electronic device 3000 and the connecting condition diagnosis apparatus 1000 is the third condition with reference to FIG. 5.

FIG. 5 shows a schematic diagram of the connecting condition diagnosis system of the present disclosure under a third condition.

Based on the potential of the output node 1240 of the connecting condition diagnosis apparatus 1000, the controller 2000 may determine the connecting condition between the electronic device 3000 and the connecting condition diagnosis apparatus 1000 as the third condition where the electrical path between the electronic device 3000 and the connecting condition diagnosis apparatus 1000 is short-circuited with the outside. Meanwhile, the third condition where the electrical path between the electronic device 3000 and the connecting condition diagnosis apparatus 1000 is short-circuited with the outside may include the following two cases of the ground short-circuit condition where the electrical path is grounded and the ground voltage thus appears, and the power source short-circuit condition where the electrical path is short-circuited with the power source and the power source voltage thus appears.

First, the ground short-circuit condition of the third condition refers to the case where the first and second port wires 3210 and 3220 are damaged due to a factor such as the external force to cause the electrical path to be short-circuited with an external metal object or grounded through the ground in a situation in which the first and second ports 3110 and 3120 of the electronic device 3000 and the first and second connection terminals 1110 and 1120 of the connecting condition diagnosis apparatus 1000 are respectively connected to each other by the wires, and the electronic device 3000 and the connecting condition diagnosis apparatus 1000 are thus electrically connected to each other. In this case, the potentials of one end and the other end of the first impedance 1210 may have the same value as the ground potential. Therefore, in the third condition according to an embodiment, the potential of the output node 1240 of the connecting condition diagnosis apparatus 1000 may have the same value as the ground voltage.

Second, the power source short-circuit condition of the third condition refers to the case where the electrical path is short-circuited with the power source Vₛ due to the external factor in a situation in which the first and second ports 3110 and 3120 of the electronic device 3000 and the first and second connection terminals 1110 and 1120 of the connecting condition diagnosis apparatus 1000 are respectively connected to each other through the first and second ports wires 3210 and 3220, and the electronic device 3000 and the connecting condition diagnosis apparatus 1000 are thus electrically connected to each other. In this case, the potentials of one end and the other end of the first impedance 1210 may be the same as the power source voltage Vₛ. Therefore, the potential of the output node 1240 included in the connecting condition diagnosis apparatus 1000 in the power source short-circuit condition of the third condition may have the same value as the power source voltage (Vₛ).

That is, the controller 2000 may diagnose, as the third condition where the electrical path is short-circuited, the ground short-circuit condition where the electrical path is grounded and the ground potential thus appears, or the power source short-circuit condition where the electrical path is short-circuited with the power source Vs and the power source voltage thus appears in the situation in which the first and second ports 3110 and 3120 of the electronic device 3000 and the first and second connection terminals 1110 and 1120 of the connecting condition diagnosis apparatus 1000 are respectively connected to each other through the first and second ports wires 3210 and 3220, and the electronic device 3000 and the connecting condition diagnosis apparatus 1000 are thus electrically connected to each other. Meanwhile, the controller 2000 may distinguish and recognize, as a 3-1-th condition, the ground short-circuit condition where the electrical path is grounded and the ground voltage thus appears, and distinguish and recognize, as a 3-2-th condition, the power source short-circuit condition where the electrical path is short-circuited with the power source and the power source voltage thus appears.

In conclusion, unlike a prior circuit only determining the connection or the disconnection, the connecting condition diagnosis apparatus in the present disclosure may diagnose the short-circuit condition by further distinguishing the short-circuit condition from the connecting conditions, thus allowing a worker to more easily identify a problem and take a measure.

The description describes a method of the controller 2000 determining the connecting condition based on the potential of the output node 1240 of the diagnosis circuit 1200 that is disposed in the connecting condition diagnosis apparatus 1000.

The controller 2000 may set predetermined first to third reference voltages to determine one of the first to third conditions based on the potential of the output node 1240 of the diagnosis circuit 1200. In detail, the controller 2000 may determine, as the first condition, the connecting condition between the electronic device 3000 and the connecting condition diagnosis apparatus 1000 when the potential of the output node 1240 is more than the predetermined first reference voltage.

In addition, the controller 2000 may determine, as the second condition, the connecting condition between the electronic device 3000 and the connecting condition diagnosis apparatus 1000 when the potential of the output node 1240 is equal to or less than the first reference voltage and more than the predetermined second reference voltage. The second reference voltage may be less than the first reference voltage.

In addition, the controller 2000 may determine, as the third condition, the connecting condition between the electronic device 3000 and the connecting condition diagnosis apparatus 1000 when the potential of the output node 1240 is less than the second reference voltage or more than the predetermined third reference voltage. The third reference voltage may be more than the first reference voltage or the second reference voltage.

In conclusion, the controller may distinguish the first to third conditions from one another by setting the first to third predetermined reference voltages.

Next, the description describes a method of the controller 2000 setting the first reference voltage, the second reference voltage, and the third reference voltage.

The power source Vs of the connecting condition diagnosis apparatus 1000 may have a voltage having a variable value rather than a fixed value. In this case, the potential of the output node 1240 may be changed based on a change in the voltage of the power source Vs or a change in a value of the resistor included in the first, second, or third impedance 1210, 1220, or 1230 that occurs based on a temperature. If the first and second reference voltages are not properly set, the controller 2000 may not determine the connecting condition between the electronic device 3000 and the connection status diagnosis device 1000. That is, it is necessary to properly set a first reference voltage range and a second reference voltage range in order for the controller 2000 to distinguish the first to third conditions from one another more reliably based on the voltage level of the potential of the output node 1240.

Accordingly, the controller 2000 of the connecting condition diagnosis system according to the present disclosure may calculate a range for recognizing the potential of the output node in consideration of a certain margin, and set predetermined first to third reference voltage ranges within the calculated range.

The description describes a method of setting the first reference voltage range.

When the rated voltage of the power source is V_{s_r}, the real part of the first impedance 1210 is R₁, the real part of the second impedance 1220 is R₂, and the real part of the third impedance 1230 is R₃, the first reference voltage may be less than a value of V_{s_r}·(R₂+R₃)/(R₁+R₂+R₃) and the first reference voltage may be more than or equal to the largest value between V_{s_r}·α·(R₂+R₃)/(R₁+R₂+R₃) and V_{s_r}·β·(R₃)/(R₁+R₃). In this case, α may be a constant having a value between 0.8 and 0.9, and β may be a constant having a value between 1.1 and 1.2.

As described above, the controller 2000 may determine, as the first condition, the connecting condition between the electronic device 3000 and the connecting condition diagnosis apparatus 1000 when the potential of the output node 1240 is more than the first reference voltage.

First, the description describes an upper limit value of the first reference voltage.

When the connecting condition between the electronic device 3000 and the connecting condition diagnosis apparatus 1000 is the first condition, the controller 2000 may accurately recognize the first condition only in a case where Vₛ·(R₂+R₃)/(R₁+R₂+R₃) which is the real part of the potential of the output node 1240, is more than the first reference voltage. Therefore, the controller 2000 may set, as a first reference voltage value, a value less than V_{s_r}·(R₂+R₃)/(R₁+R₂+R₃) in consideration of a rated voltage Vs_r of the power source.

Therefore, the upper limit value of the first reference voltage is required to be less than. V_{s_r}·(R₂+R₃)/(R₁+R₂+R₃).

Next, the description describes a lower limit value of the first reference voltage.

In order to prevent the potential of the output node 1240 in the first condition from being mistakenly recognized as the second condition, the first reference voltage is required to be sufficiently larger than V_{s_r}·(R₃)/(R₁+R₃) which is the real part of the potential of the output node 1240 in the second condition. Required is a difference between the lower limit value of the first reference voltage and the potential of the output node in the second condition by multiplying the real part of the potential of the output node 1240 in the second condition by a constant more than β. β may be the constant having the value between 1.1 and 1.2. Therefore, in consideration of the rated voltage Vs_r of the power source, the lower limit value of the first reference voltage may be organized as an expression shown below.

$${V}_{s\_r} \cdot β \cdot ( {R}_{3} ) / ( {R}_{1} + {R}_{3} )$$

However, depending on the design of the diagnosis circuit 1200, established is an expression shown below.

$${V}_{s\_r} \cdot ( {R}_{2} + {R}_{3} ) / ( {R}_{1} + {R}_{2} + {R}_{3} ) \leq {V}_{s\_r} \cdot β \cdot ( {R}_{3} ) / ( {R}_{1} + {R}_{3} )$$

In this case, even though the potential of the output node 1240 in the first condition is output, the potential less than the lower limit value of the first reference voltage may be output and diagnosed as the second condition. Therefore, to avoid the misrecognition, the controller needs to set an additional condition of the lower limit value of the first reference voltage.

Therefore, the controller 2000 may set the lower limit value of the first reference voltage to have a value less than V_{s_r}·(R₂+R₃)/(R₁+R₂+R₃). In detail, the lower limit value of the first reference voltage may be set by multiplying the real part of the potential of the output node in the first condition by α, which is a constant less than 1. α may be the constant having the value between 0.8 and 0.9. Therefore, the additional condition of the lower limit value of the first reference voltage may be organized as an expression shown below.

$${V}_{s\_r} \cdot α \cdot ( {R}_{2} + {R}_{3} ) / ( {R}_{1} + {R}_{2} + {R}_{3} )$$

In conclusion, the controller 2000 may set the lower limit value of the first reference voltage to be more than or equal to the largest value of V_{s_r}·α·(R₂+R₃)/(R₁+R₂+R₃) and V_{s_r}·β·(R₃)/(R₁+R₃) by adding a certain margin using the constants α and β for V_{s_r}·(R₂+R₃)/(R₁+R₂+R₃) and V_{s_r}·(R₃)/(R₁+R₃) based on the rated voltage V_{s_r}, of the power source. As an example, the controller 2000 may change the values of α and β, and receive the values of α and β from the outside.

The description describes the second reference voltage range.

When the rated voltage of the power source is V_{s_r}, the real part of the first impedance 1210 is R₁, and the real part of the third impedance 1230 is R₃, the second reference voltage may be less than the value of V_{s_r}·γ·(R₃)/(R₁+R₃), and here γ may be the constant having the value between 0.8 and 0.9.

As described above, the controller 2000 may determine, as the second condition, the connecting condition between the electronic device 3000 and the connecting condition diagnosis apparatus 1000 when the potential of the output node 1240 is less than the first reference voltage and is more than the predetermined second reference voltage. In this case, it is necessary to set the second reference voltage range with a certain margin to prevent the controller 2000 from incorrectly determining the second condition as the ground short-circuit condition of the third condition due to a fluctuation in the power source voltage. In detail, when the connecting condition between the electronic device 3000 and the connecting condition diagnosis apparatus 1000 is the second condition, the real part of the potential of the output node 1240 may have a value of Vₛ·(R₃)/(R₁+R₃). In this case, the second reference voltage is required to be sufficiently less than the potential of the output node 1240 in the second condition in order for the potential of the output node 1240 in the second condition not to be misrecognized as the ground short-circuit condition of the third condition.

Therefore, the value of V_{s_r}·γ·(R₃)/(R₁+R₃) based on the rated voltage V_{s_r} of the power source may be multiplied by an arbitrary constant γ to leave a certain margin. Here, γ may be the constant having the value between 0.8 and 0.9. As an example, the controller 2000 may change the value of γ like α and β, and receive the value of γ from the outside.

The description describes the third reference voltage range.

When the rated voltage of the power source is V_{s_r}, the real part of the first impedance is R₁, the real part of the second impedance is R₂, and the real part of the third impedance is R₃, the third reference voltage may be more than the value of V_{s_r}·δ·(R₂+R₃)/(R₁+R₂+R₃), and here, δ may be a constant having a value of 1.05 or more.

As described above, the controller 2000 may determine, as the third condition, the connecting condition between the electronic device 3000 and the connecting condition diagnosis apparatus 1000 when the potential of the output node 1240 is less than the second reference voltage or more than the predetermined third reference voltage.

In this case, it is necessary to set the third reference voltage range with a certain margin to prevent the controller 2000 from incorrectly determining the first condition as the power source short-circuit condition of the third condition due to the fluctuation in the power source voltage. In detail, when the connecting condition between the electronic device 3000 and the connecting condition diagnosis apparatus 1000 is the first condition, the real part of the potential of the output node 1240 may output Vₛ·(R₂+R₃)/(R₁+R₂+R₃). The third reference voltage is required to be sufficiently larger than the potential of the output node 1240 in the first condition in order for the potential of the output node 1240 in the first condition not to be misrecognized as the power source short-circuit condition of the third condition. The term “sufficiently larger” or “sufficiently large” is a mathematical term that signifies a value that is exceedingly large or extensive or being magnitudes (or multiples) larger, e.g., as compared to being simply “larger” than a particular value. Similarly, the term “sufficiently less than” signifies a value that is exceedingly less than or being magnitudes (or multiples) smaller, e.g., as compared to being simply “less than” a particular value.

Therefore, the value of V_{s_r}·(R₂+R₃)/(R₁+R₂+R₃) based on the rated voltage V_{s_r} of the power source may be multiplied by an arbitrary constant δ to leave a certain margin. Here, δ may be a constant having a value of 1.1 or more. A value range of δ may be more than or equal to 1.1, or less than or equal to 1.2. In an embodiment, the controller 2000 may change the value of δ like α, β and γ, and receive the value of δ from the outside.

In conclusion, the controller 2000 may set each of the first to third reference voltage ranges with a certain margin to thus more reliably determine the connecting condition between the electronic device 3000 and the connecting condition diagnosis apparatus 1000.

As set forth above, unlike the prior system capable of only determining whether the device is connected to or disconnected from the system, the connecting condition diagnosis apparatus and system according to the present disclosure as described above may further diagnose the short-circuit condition occurring in the connection line with the device, thus enabling more easy failure cause identification and response thereto and more efficient device management.

Although the embodiments of the present disclosure are described as above, the embodiments disclosed in the present disclosure are provided not to limit the spirit of the present disclosure, but to fully describe the present disclosure. Therefore, the spirit of the present disclosure may include not only each disclosed embodiment but also a combination of the disclosed embodiments. Further, the scope of the present disclosure is not limited by these embodiments. That is, it is apparent to those skilled in the art to which the present disclosure pertains that various variations and modifications could be made without departing from the spirit and scope of the appended claims, and all such appropriate variations and modifications should be considered as falling within the scope of the present disclosure as equivalents.

What is claimed is:

1. A connecting condition diagnosis apparatus connected to an electronic device including first and second ports electrically short-circuited with each other, the apparatus comprising:
first and second connection terminals respectively connected to the first and second ports of the electronic device by wires; and
a diagnosis circuit connected to the first and second connection terminals and configured to diagnose whether the connecting condition diagnosis apparatus is connected to the electronic device,
wherein the diagnosis circuit includes a first impedance between the first connection terminal and the second connection terminal, and
wherein the first impedance includes a passive element.

2. The apparatus of claim 1,
wherein the diagnosis circuit further includes a second impedance between the first connection terminal and a power source; and
wherein the diagnosis circuit is configured to externally provide an output node comprising a node in contact with the first impedance, the first connection terminal, and the second impedance, and
wherein the second impedance includes a passive element.

3. The apparatus of claim 2,
wherein the diagnosis circuit further includes a third impedance between the second connection terminal and ground, and
wherein the third impedance includes a passive element.

4. The apparatus of claim 3, wherein each of the first impedance, the second impedance, and the third impedance includes a resistor.

5. The apparatus of claim 4, wherein, when a rated voltage of the power source is V_{s_r}, a real part of the first impedance is R₁, a real part of the second impedance is R₂, and a real part of the third impedance is R₃,
the real part of the first impedance, the real part of the second impedance, and the real part of the third impedance satisfy an expression below:
$$\vert {V}_{s\_r} \cdot ( {R}_{2} + {R}_{3} ) / ( {R}_{1} + {R}_{2} + {R}_{3} ) - {V}_{s\_r} \cdot {R}_{3} / ( {R}_{1} + {R}_{3} ) \vert \geq {V}_{s\_r} / 10.$$

6. The apparatus of claim 4, wherein, when a rated voltage of the power source is V_{s_r}, a real part of the first impedance is R₁, a real part of the second impedance is R₂, and a real part of the third impedance is R₃,
the real part of the first impedance, the real part of the second impedance, and the real part of the third impedance simultaneously satisfy Expression 1 and Expression 2 shown below:
$$\vert {V}_{s\_r} - {V}_{s\_r} \cdot ( {R}_{2} + {R}_{3} ) / ( {R}_{1} + {R}_{2} + {R}_{3} ) \vert \geq {V}_{s\_r} / 10 , and \qquad [ Equation 1 ]$$
$$\vert {V}_{s\_r} \cdot ( {R}_{2} + {R}_{3} ) / ( {R}_{1} + {R}_{2} + {R}_{3} ) \vert \geq {V}_{s\_r} / 10. \qquad [ Equation 2 ]$$

7. The apparatus of claim 4, wherein when a rated voltage of the power source is V_{s_r}, a real part of the first impedance is R₁ and a real part of the third impedance is R₃,
the real part of the first impedance, the real part of the second impedance, and the real part of the third impedance simultaneously satisfy Expression 3 and Expression 4 shown below:
$$\vert {V}_{s\_r} - {V}_{s\_r} \cdot {R}_{3} / ( {R}_{1} + {R}_{3} ) \vert \geq {V}_{s\_r} / 10 , and \qquad [ Expression 3 ]$$
$$\vert {V}_{s\_r} \cdot {R}_{3} / ( {R}_{1} + {R}_{3} ) \vert \geq {V}_{s\_r} / 10. \qquad [ Expression 4 ]$$

8. A connecting condition diagnosis system, the system comprising:
a connecting condition diagnosis apparatus connected to an electronic device including first and second ports electrically short-circuited with each other; and
a controller connected to the connecting condition diagnosis apparatus,
wherein the connecting condition diagnosis apparatus includes a first connection terminal and a second connection terminal respectively connected to the first and second ports of the electronic device by wires, the connecting condition diagnosis circuit connected to the first and second connection terminals and configured to diagnose whether the connecting condition diagnosis apparatus is connected to the electronic device,
wherein the connecting condition diagnosis circuit includes:
a first impedance between the first connection terminal and the second connection terminal; and
a second impedance disposed between the first connection terminal and a power source; and
a third impedance between the second connection terminal and ground,
wherein the first impedance, the second impedance, and the third impedance are passive elements,
wherein the connecting condition diagnosis circuit is configured to externally provide an output node which is a node in contact with the first impedance, the first connection terminal, and the second impedance, and
wherein, based on a potential of an output node of the connecting condition diagnosis apparatus, the controller is configured to diagnose a connecting condition between the electronic device and the connecting condition diagnosis apparatus as one of:
a first condition where any one of the first and the second connection terminals of the connecting condition diagnosis apparatus is not connected to the first or second port of the electronic device;
a second condition where the electronic device and the connecting condition diagnosis apparatus are connected to each other; or
a third condition where an electrical path between the electronic device and the connecting condition diagnosis apparatus is short-circuited with the outside.

9. The system of claim 8, wherein the controller is further configured to determine, as the first condition, the connecting condition between the electronic device and the connecting condition diagnosis apparatus in response to the potential of the output node being more than a predetermined first reference voltage.

10. The system of claim 9,
wherein the controller is further configured to, as the second condition, the connecting condition between the electronic device and the connecting condition diagnosis apparatus in response to the potential of the output node being less than the first reference voltage and greater than a predetermined second reference voltage, and
wherein the second reference voltage is less than the first reference voltage.

11. The system of claim 10,
wherein the controller is configured to determine, as the third condition, the connecting condition between the electronic device and the connecting condition diagnosis apparatus in response to the potential of the output node being less than the second reference voltage, or greater than a predetermined third reference voltage, and
wherein the third reference voltage is greater than the first reference voltage or the second reference voltage.

12. The system of claim 10, wherein when a rated voltage of the power source is V_{s_r}, a real part of the first impedance is R₁, a real part of the second impedance is R₂, and a real part of the third impedance is R₃,
the first reference voltage is less than a value of V_{s_r}·(R₂+R₃)/(R₁+R₂+R₃), and the first reference voltage is more than or equal to a largest value between V_{s_r}·α·(R₂+R₃)/(R₁+R₂+R₃) and V_{s_r}·β·(R₃)/(R₁+R₃), and
where, α is a constant having a value between 0.8 and 0.9, and β is a constant having a value between 1.1 and 1.2.

13. The system of claim 10, wherein, when a rated voltage of the power source is V_{s_r}, a real part of the first impedance is R₁, a real part of the second impedance is R₂, and a real part of the third impedance is R₃,
the second reference voltage is less than a value of V_{s_r}·γ·(R₃)/(R₁+R₃), and
where, γ is a constant having a value between 0.8 and 0.9.

14. The system of claim 11, wherein when a rated voltage of the power source is V_{s_r}, a real part of the first impedance is R₁, a real part of the second impedance is R₂, and a real part of the third impedance is R₃,
the third reference voltage is more than a value of V_{s_r}·δ·(R₂+R₃)/(R₁+R₂+R₃), and
where, δ is a constant having a value of 1.1 or more.

15. The system of claim 10, wherein, in response to the second reference voltage being sufficiently less than the potential of the output node in the second condition, the controller is further configured not to misdiagnose the potential of the output node in the second condition as the third condition.

16. The system of claim 11, wherein, in response to the third reference voltage being sufficiently larger than the potential of the output node in the first condition, the controller is further configured to not misdiagnose the potential of the output node in the first condition as the third condition.

17. The system of claim 11, wherein, based on at least one of the first reference voltage, the second reference voltage, the third reference voltage, or any combination thereof, the controller is further configured to diagnose at least one of a connection between the system and the electronic device, a condition of the electronic device, or a combination thereof.
